(19) United States
(12) Patent Application Publication
(10) Pub. No.: US 2025/0335660 A1
(43) Pub. Date: Oct. 30, 2025

(54) APPARATUSES AND METHODS FOR COUPON MODELING

(71) Applicant: The Boeing Company, Arlington, VA (US)

(72) Inventors: Raymond T. Condon, Saint Louis, MO (US); Brian P. Justusson, Saint Charles, MO (US); Nathan A. Ashmore, Saint Louis, MO (US)

(21) Appl. No.: 18/649,845

(22) Filed: Apr. 29, 2024

(51) Int. Cl. G06F 30/23; G06F 30/15

(52) U.S. Cl. CPC G06F 30/23; G06F 30/15

(57) ABSTRACT

Methods comprising generating a coupon finite element model (FEM) comprising coupon elements. Examples of the methods further comprise determining a difference between a global-element output of global elements of a global FEM and a coupon-element output of the coupon elements of the coupon FEM. Examples of the global-element output and the coupon-element output comprise one or more of a physical characteristic, dimension, and displacement. An apparatus comprising non-volatile memory, instructions stored on the non-volatile memory, and a processor configured to execute the instructions. Examples of the instructions include generating a coupon FEM comprising coupon elements and determining a difference between a global-element output of global elements of a global FEM and a coupon-element output of the coupon elements of the coupon FEM.

### FIELD

The present disclosure relates to apparatuses and methods for coupon modeling.

### BACKGROUND

When designing structures or apparatuses, testing of the structure or a portion of the structure is often used to demonstrate sufficient capability. For example, landing gears or wing sections are often tested. Testing may be conducted physically or using virtual models. Coupons are commonly used to conduct such tests. A coupon is a component or an apparatus designed to simulate or model a portion of a larger assembly. Testing requires time, money, and resources such as physical material and computation. In many cases, specific structures lack a coupon or apparatus analogue resulting in the requirement to test a larger, more costly structure. Accordingly, there is a need to design and conduct testing efficiently to minimize resource expenditure.

### SUMMARY

This application discloses methods and apparatuses for modeling coupons. Examples of the methods comprise generating a coupon finite element model (FEM) comprising coupon elements, and determining a difference between a global-element output of global elements of a global FEM and a coupon-element output of the coupon elements of the coupon FEM. Examples of the global-element output and the coupon-element output comprise one or more of a physical characteristic, a dimension, and a displacement.

The disclosure is further directed to an apparatus comprising non-volatile memory, instructions stored on the non-volatile memory, and a processor configured to execute the instructions. Examples of the instructions include generating a coupon FEM comprising coupon elements and determining a difference between a global-element output of global elements of a global FEM and a coupon-element output of the coupon elements of the coupon FEM.

### BRIEF DESCRIPTION OF THE DRAWINGS

FIG. 1 is a schematic flowchart representing methods according to the present disclosure.

FIG. 2A depicts an example of a global FEM of an aircraft.

FIG. 2B depicts an example of a global FEM of a wing section.

FIG. 2C depicts a partial view of the wing section of FIG. 2B.

FIG. 3 depicts an example of a coupon FEM.

FIG. 4 is a schematic diagram representing an apparatus according to the present disclosure.

FIG. 5 is a side view of an example of a physical coupon.

FIG. 6 is a top isometric view of the example physical coupon of FIG. 5

FIG. 7 is an exploded view of the example physical coupon of FIG. 5.

### DESCRIPTION

Methods and apparatuses for generating and utilizing finite element models (FEMs) are disclosed. An example of the disclosed methods and apparatuses generates a coupon FEM and determines a difference between the generated coupon FEM and a global FEM to evaluate the durability and damage performance of aircraft coatings applied over joined structures.

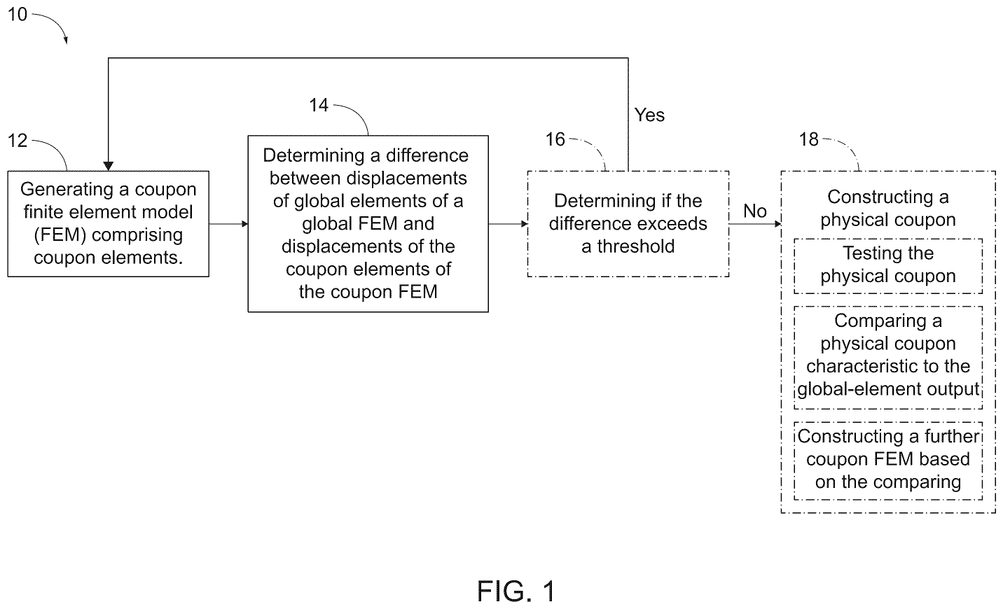

FIG. 1 schematically provides a flowchart that represents illustrative, non-exclusive examples of methods according to the present disclosure. In FIG. 1, some steps are illustrated in dashed boxes indicating that such steps may be optional or may correspond to an optional version of a method according to the present disclosure. That said, not all methods according to the present disclosure are required to include the steps illustrated in solid boxes. The methods and steps illustrated in FIG. 1 are not limiting, and other methods and steps are within the scope of the present disclosure, including methods having greater than or fewer than the number of steps illustrated, as understood from the discussions herein.

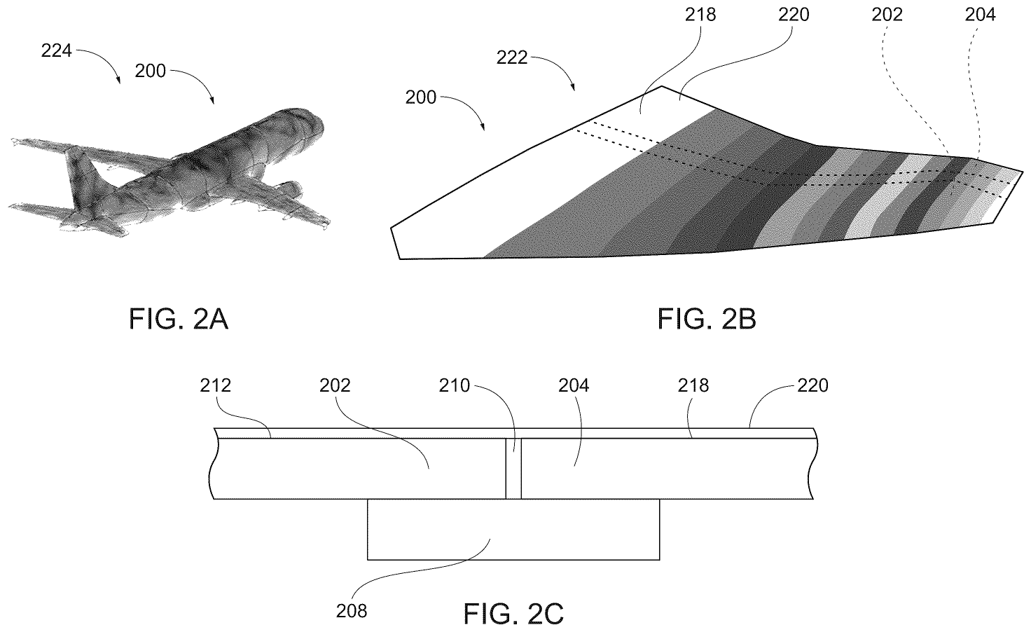

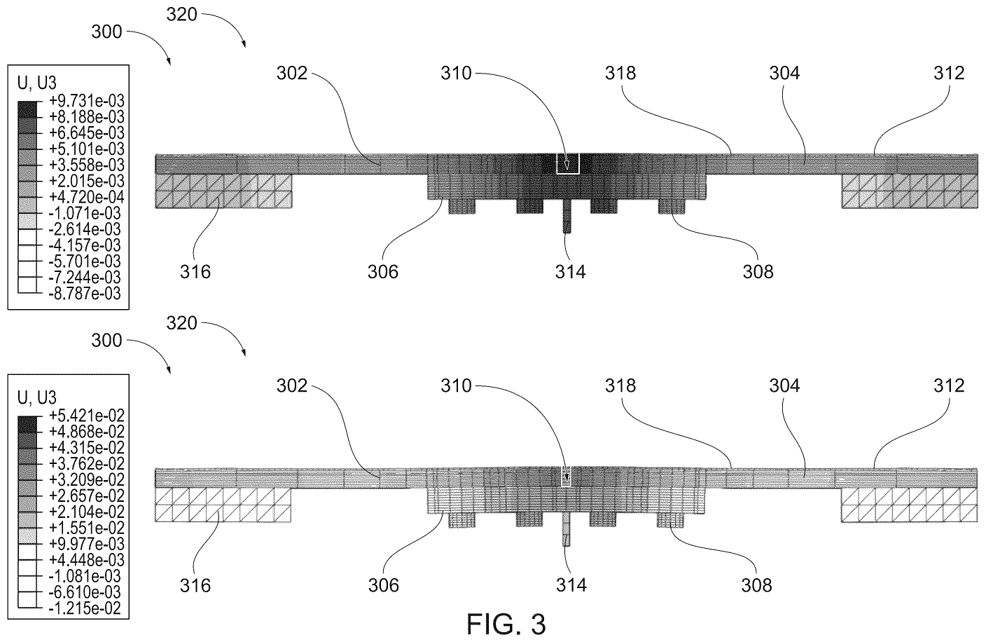

As schematically illustrated in FIG. 1, methods 10 comprise generating 12 a coupon finite element model (FEM) comprising coupon elements, and determining 14 a difference between a global-element output of global elements of a global FEM and a coupon-element output of the coupon elements of the coupon FEM. The global-element output and the coupon-element output comprise one or more of a physical characteristic, a dimension, and a displacement. Non-limiting examples of global FEM and global elements are depicted in FIGS. 2A-C as global FEMs 200 and global elements representing skin panels 202, 204, a connection 208, a gap 210, an outer surface 212, and a coating 218. Non-limiting examples of a coupon FEM and coupon elements are depicted as coupon FEM 300 and coupon elements 302-318 in FIG. 3.

The difference generated by the method 10 of FIG. 1 is a relationship between a generated coupon FEM and a global FEM. Global FEMs and coupon FEMs are described in further detail below. An example of a global FEM comprises a model of a structure, a vehicle, an aircraft, or other object of interest. An example of a coupon is a sample used for testing. An example of a coupon FEM comprises a model of an apparatus used for testing.

The relationship between the generated coupon FEM and the global FEM is determined via a difference between an output of the coupon FEM and the global FEM. A non-limiting, illustrative example is a global FEM representing a model of an aircraft wing and a coupon FEM modeling a panel of the aircraft wing. In this example, an output of the coupon FEM is a stiffness of the panel, and the output of the global FEM is a stiffness in a portion of a skin of the aircraft wing. The difference between the output of the coupon FEM and the global FEM measures how closely the coupon FEM approximates the respective portion of the global FEM. In a similar example, an output of a global FEM is a movement of a fastener in a wing, and an output of the coupon FEM is movement of a fastener in a panel. In this example, the difference between the outputs is a measure of how closely the fastener's movement in the coupon FEM approximates the movement of the fastener of the global FEM. Other examples of methods 10 are described below.

An example of the method 10 is applied to aircraft coatings. In this example, a coupon FEM is generated comprising coupon elements representing at least a joined structure and a coating. A difference is determined between an output of the coupon FEM and an output of a global FEM comprising a model of an aircraft. In a further specific example, the method 10 is used to examine durability and damage tolerance of coatings covering joined structures in an aircraft. In this example, the output of a coupon FEM is one or more of displacement of the joined structures, strain in the coating, and physical damage to the coating, and the output of the global FEM is one or more of displacement of joined structures and strain in a coating. Another example of the method 10 generates coupon FEMs to represent structural failure modes.

In general, FEMs subdivide a large system into smaller parts called finite elements. In other words, a component or a structure is divided into a mesh of the finite elements. Finite element models provide boundary values, which allow for complex systems of equations to be approximated as a simpler system of algebraic equations.

FIGS. 2B-C depicts an example of a global FEM comprising a model of a wing 222. FIG. 2C depicts an exemplary cross-section of a portion of the wing 222. As seen in FIG. 2B, the modeled wing 222 is comprised of many small elements. In one example, the modeled aircraft 224 of the global FEM of FIG. 2A has element sizes of about 4 inches. An example of the modeled wing 222 of the global FEM of FIG. 2B has element sizes as small as 0.4-0.25 inches. FIG. 3 depicts a further example of a coupon FEM 300 comprising a model of a coupon 320, and the coupon FEM 300 comprises a plurality of small elements.

An example of a global FEM is a model of a structure such as an aircraft. An example of a global-FEM can be further described as a coarse grid analytical representation of a load-bearing structure.

Examples of global FEMs 200 are depicted in FIGS. 2A-C. Examples of a global FEM are a model of one or more of a structure, a portion of a structure, a vehicle, a portion of a vehicle, an aircraft, or a portion of an aircraft. A further example of a global FEM is a model of a portion of a structure or object, for example, a wing of an aircraft, a chassis of a vehicle, or a frame of a structure.

Examples of global FEMs vary in detail and characteristics included in the FEM. Some examples of global FEMs comprise a portion of an overall structure, for example a model of a frame of an aircraft. Other examples of global FEMs include models of an overall structure or object and all of the comprised components. One example of such a global FEM is an aircraft, including many components such as wings, a fuselage, a tail, a rudder, landing gear, skin panels, joints between panels, fasteners, and windows. Further examples of a global FEM comprise a portion of an overall structure and all components that comprise the portion. An example of this type of global FEM is a model of a wing of an aircraft comprising panels, frame, fasteners, joints, flight control panels, and fuel storage. Another example of a global FEM is a model of one or more of an aircraft wing 222, a fuselage, an empennage, and a chassis, as depicted in FIGS. 2A-C. Still further examples of a global FEM 200 compromise global elements representing skin panels 202, 204, a connection 208, a gap 210, an outer surface 212, and a coating 218, as depicted in FIGS. 2B-C.

Examples of global FEMs also vary according to conditions represented. Some examples of conditions represented in a global FEM comprise movement, temperature, pressure, load, stress, strain, environment, humidity, cyclic loading, fatigue, damage, deformation, friction, and metal plasticity. One example of a global FEM is depicted in FIGS. 2B-C which includes a model of an aircraft wing 222 comprising a gap 210 in a skin 220. An example of the global FEM comprises a displacement of the gap 210 due to conditions such as a load on the wing or thermal expansion. Another example of the global FEM comprises damage to the outer surface of the wing due to movement of fasteners.

The examples of FIGS. 2A-C depict strain in outer surfaces of the aircraft 224 and strain and deflection in the wing 222. The examples depicted in FIGS. 2A-C use shade gradients to depict various levels of strain. Other examples of global FEMs comprise modeling different loads and different temperatures. Still further examples of global FEMs comprise modeling fasteners and other structures beneath the outer surfaces.

In contrast to global FEMs, a coupon FEM models a coupon. A coupons is an element, structure, or apparatus typically used for testing. Examples of a coupon FEM comprise elements representing a single piece coupon, an apparatus, or an assembly of a plurality of elements. Some examples of a coupon FEM comprise elements representing coatings, panels, beams, parts, components, fasteners, supports, connections, and parts thereof. An example of a coupon FEM is depicted in FIG. 3. The coupon FEM 300 of FIG. 3 includes coupon elements 302-318 comprising panel elements representing two panels 302, 304, and support elements representing structures attached to the two panels 302, 304. In a further example, the support elements represent one or more of a backing 306, a connection 308 between the backing and the two panels, a spar 314, and tabs 316. An example of the connection 308 comprises one or more of a bolt, a bond, a rivet, a flocking, or an adhesive. An example of the coupon elements 302-318 comprise surface elements representing an outer surface 312. A further example of coupon elements 302-318 may comprise part elements representing the two panels and joining elements representing components joining the two panels.

Similarly to global FEMs, coupon FEMs vary according to conditions represented. Some examples of the conditions represented in a coupon FEM comprise movement, temperature, pressure, load, stress, strain, environment, humidity, cyclic loading, fatigue, damage, deformation, friction, and metal plasticity. The example of the coupon FEM of FIG. 3 comprises a displacement of the joint 310. Displacement in a coupon FEM may be due to conditions such as a load or thermal expansion. FIG. 3 also depicts displacement and strain in the modeled apparatus. As illustrated, a center region near joint 310 has a higher strain, whereas a region distal from the joint 310 has a lower strain. Other examples of a coupon FEM model strain in a structure due to thermal expansion. Still further examples of a coupon FEM model damage caused by fastener movement, for example connections 308 of FIG. 3.

Another example of the coupon FEM simulates one or more physical characteristics, wherein the physical characteristics comprise one or more of stiffness, thermal expansion, friction, bearing damage, and metal plasticity. Coupon FEMs modeling these types of characteristics have many uses, such as determining wear caused by fastener movement and determining plastic deformation in a panel or a support.

Examples of coupon FEMs comprise coating elements representing a coating 318. An example of a coupon FEM modeling a coating may be used for aircraft. In aircraft, multiple layers of coatings are often applied to the outer mold line of the aircraft for corrosion prevention. Such aircraft coatings may be applied over areas of a joined structure that are susceptible to loadings and displacements that damage the coatings. In a fastened structure, fastener rotation also may damage the coatings. Repair to coatings adds significant expense to aircraft maintenance. Accordingly, an example of method 10 applied to generate a coupon FEM modeling a coating of an aircraft is used to evaluate durability and damage of aircraft coatings. Modeling the durability and damage may lead to a reduction in repair and test expenditures.

Examples of methods to characterize the durability of aircraft outer mold line coating comprise generating a coupon FEM subjected to loads derived from an aircraft platform global FEM. Examples of the method further include constructing a physical coupon to represent field aircraft conditions.

In the example of coating elements representing coating 318, the coating elements are positioned over coupon elements representing the joint 310 between the two panels 302, 304. In one example, an output of the coupon FEM is a displacement of the represented joint, a strain in the coating, and/or damage to the coating. In further examples, the coating elements represent a coating thickness which is at least 0.025 millimeters (mm) and at most 5 mm, at least 0.05 mm and at most 4 mm, at least 0.1 mm and at most 3 mm, at least 0.2 mm and at most 2 mm, and at least 0.5 mm and at most 1 mm.

The example of FIG. 3 depicts displacement and strain in represented coupon 320. The example depicted in FIG. 3 uses shade gradient to depict various levels of strain. Other examples of coupon FEMs as depicted in FIG. 3 comprise modeling different loads and different temperatures. Still further examples of coupon FEMs similar to FIG. 3 comprise modeling other types of fasteners and different materials for coupon elements.

Outputs of a global FEM and a coupon FEM vary based on the object, structure, vehicle, aircraft, or other object modeled. Outputs of a global FEM and a coupon FEM vary based on characteristics that are modeled. As discussed above, the global-element output and the coupon-element output comprise one or more of a physical characteristic, dimension, and displacement. In a further example, the physical characteristic, dimension, and displacement comprises one or more of friction, damage, metal plasticity, stiffness, displacement, fastener movement, thermal effects, dimension misalignment, and clearance.

An example of an output of a global FEM is a strain in a skin of an aircraft wing under load. Another example of an output of a global FEM is one or more of a load, a displacement, a strain, a stress, and a deformation in a support structure of the aircraft. Yet another example of an output of a global FEM is a gap displacement in global elements representing a gap 210 in a skin 220, as depicted in FIGS. 2B-C. As a further example, an output of a global FEM and a coupon FEM is movement of structures beneath a coating and a corresponding strain within the coating.

Further examples of an output of a coupon FEM depend on the apparatus modeled. An example of an output of a coupon FEM is movement of a fastener and a corresponding damage to the structure surrounding the fastener. A further example of a coupon-element output is yielding in an element of the coupon FEM. Another example of a coupon-element output is a change in dimension of coupon elements representing structures. Examples of coupon elements that change dimension are elements representing coating 318. A further output of the coupon FEM is a distance between structures, such as joint 310.

Examples of outputs of coupon FEMs also correspond to outputs of global FEMs. For example, in a coupon FEM 300 designed to simulate wing 222 of global FEM 200, an output of global FEM 200 compromises a gap displacement in global elements representing a gap 210 in a skin 220, and an output of coupon FEM 300 comprises a change in dimension of a joint 310 between the two panels 302, 304.

Further examples of coupon-element outputs comprise a change in dimension representing damage. An example of a change in dimension representing damage is necking of a support structure due to plastic deformation. Another example of a change in dimension representing damage is a crack caused by strain or fatigue. A further example of a change in dimension representing damage is delamination of a coating.

Outputs of a coupon FEM are compared to outputs of a global FEM, for example, by determining a difference. As discussed above, an example of an output of a coupon FEM or global FEM comprises a displacement, movement, temperature, pressure, load, stress, strain, environment, humidity, cyclic-loading, fatigue, damage, deformation, friction, and metal plasticity. In one example, a difference is determined between a coupon-element output of a change in dimension of a joint 310 between the two panels 302, 304, as depicted in FIG. 3, and the global-element output compromising a gap displacement in global elements representing a gap 210 in a skin 220, as depicted in FIGS. 2B-C. A further example includes determining a difference between an output of a strain within the elements representing coating 218 of global FEM and an output of a strain within the elements representing coating 318 of coupon FEM 300.

Examples of outputs of global FEMs and coupon FEMs are also compared by other methods, such as fractions, standard deviation, and error calculations.

With reference to FIG. 1, some examples of method 10 further comprise determining 16 if the difference exceeds a threshold, wherein the difference is a difference between a global-element output of a global FEM and a coupon-element output of a coupon FEM. The threshold for a difference will vary depending on the coupon FEM and the global FEM. Examples of a threshold are 2%, 1%, 0.5%, 0.1%, or 0.05% of an output of the global FEM. Another example of a threshold is 1, 2, or 3 standard deviations of an output of the global FEM. Still further examples are based on machine tolerance or industry standards. If a difference between an output of a global FEM and an output of a coupon FEM is greater than a threshold, then the method continues by generating a subsequent coupon FEM and determining a difference between outputs of the subsequent coupon FEM and the global FEM. Examples of the method continue to perform the method 10 as depicted in FIG. 1, until the determined difference is below the threshold. In other words, examples of the method continue to generate coupon FEMs until a difference between the coupon FEM and the global FEM is sufficiently small.

In one example, the global FEM models an aircraft, and the coupon FEM models panels, supports, and a coating designed to simulate a section of a wing. In such example, the modeled coating of the coupon FEM is positioned over the modeled joint between the two panels, and the output of the coupon FEM is the displacement of the joint. The output of the coupon FEM is compared to an output of a global FEM, which in this example is a displacement of a gap in a skin of the aircraft. If a difference between the output of the coupon FEM and the output of the global FEM is not sufficiently small, then the coupon FEM does not adequately represent the global FEM. In other words, the difference exceeds a threshold.

In this example, if the difference exceeds the threshold, then a second coupon FEM is generated with one or more elements that differ from the first coupon FEM. A second difference between the output of the second coupon FEM and the global FEM is determined. If the second difference is greater than the threshold, then a third coupon FEM is generated. In this example, the process continues until the difference falls below the threshold. In one example, the method 10 further comprises constructing 18 a physical coupon based on the coupon FEM in response to the difference being less than the threshold.

In this way, the methods and apparatuses of the application reduce a difference between a coupon FEM and a global FEM. Reducing the difference between a coupon FEM and a global FEM may lead to reduction of time, money, and resources required to conduct accurate tests. In one example, a physical coupon is constructed based on a coupon FEM. However, in another example, the physical coupon is not constructed until the difference between the output of the coupon FEM and the global FEM falls below the threshold. Thus, this example would prevent production of physical coupons that do not adequately represent the global FEM.

An example of the method is depicted in FIG. 1. FIG. 1 depicts a method 10 comprising generating 12 a coupon finite element model (FEM) comprising coupon elements and determining 14 a difference between a global-element output of global elements of a global FEM and a coupon-element output of the coupon elements of the coupon FEM. One example depicted in FIG. 1 further comprises determining 16 if the difference exceeds one or more threshold. One example of FIG. 1 further comprises, responsive to the first difference exceeding the threshold, generating 12 a second coupon FEM comprising second coupon elements, wherein at least one of the second coupon elements is different from the first coupon elements. This example also includes determining 14 a second difference between the global-element output of the global elements of the global FEM and a second coupon-element output of the second coupon elements.

In further examples responsive to the second difference exceeding a second threshold, the method proceeds to generating 12 a third coupon FEM comprising third coupon elements, wherein at least one of the third coupon elements is different from the second coupon elements and from the first coupon elements. This example further includes determining 14 a third difference between the global-element output of the global elements of the global FEM and a third coupon-element output of the third coupon elements of the third coupon FEM.

In some examples, successive coupon FEMs are designed to more accurately simulate the global FEM than the previous coupon FEM. Thus, in these examples, a third difference is less than a second difference and the second difference is less than a first difference, where the differences are between respective coupon FEMs and the global FEM.

Some elements of successive coupon FEMs are the same as or similar to those of previous coupon FEMs. However, one or more elements of successive coupon FEMs will be different from previous coupon FEMs. In some examples, the different elements of the successive coupon FEMs will reduce the difference between the outputs of the successive coupon FEMs and the global FEM, relative to previous coupon FEMs. In one example, second coupon elements 302-318 represent a backing 306 or a connection 308 that is different from the first coupon elements 302-318. In a further example, the second coupon elements comprise connection elements representing an additional connection that is not present in the first coupon elements. In yet another example, second coupon elements represent at least one material that is different from the first coupon elements.

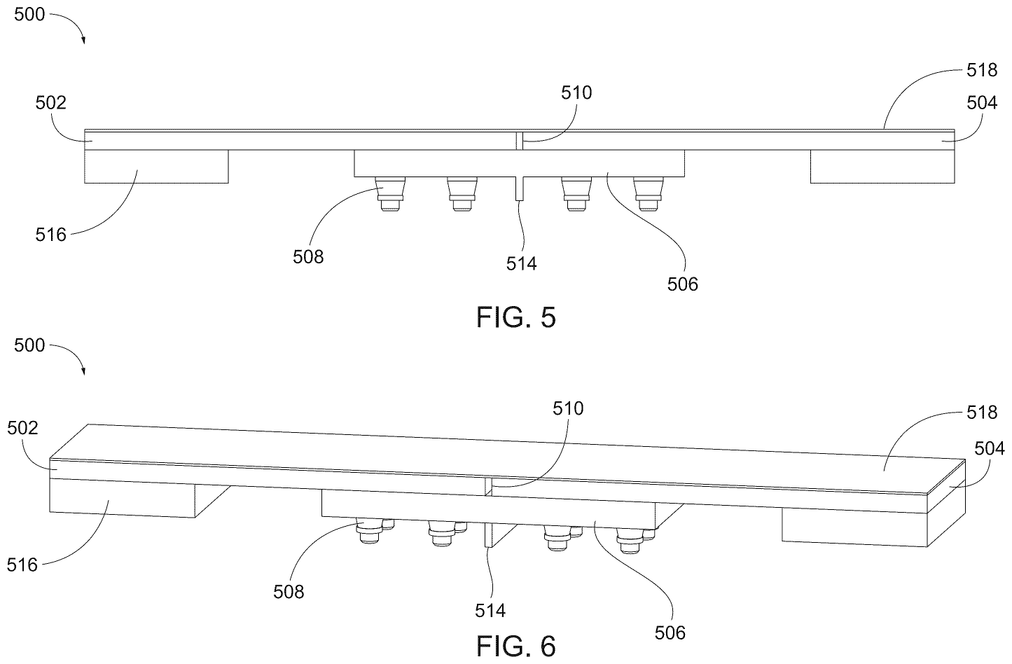

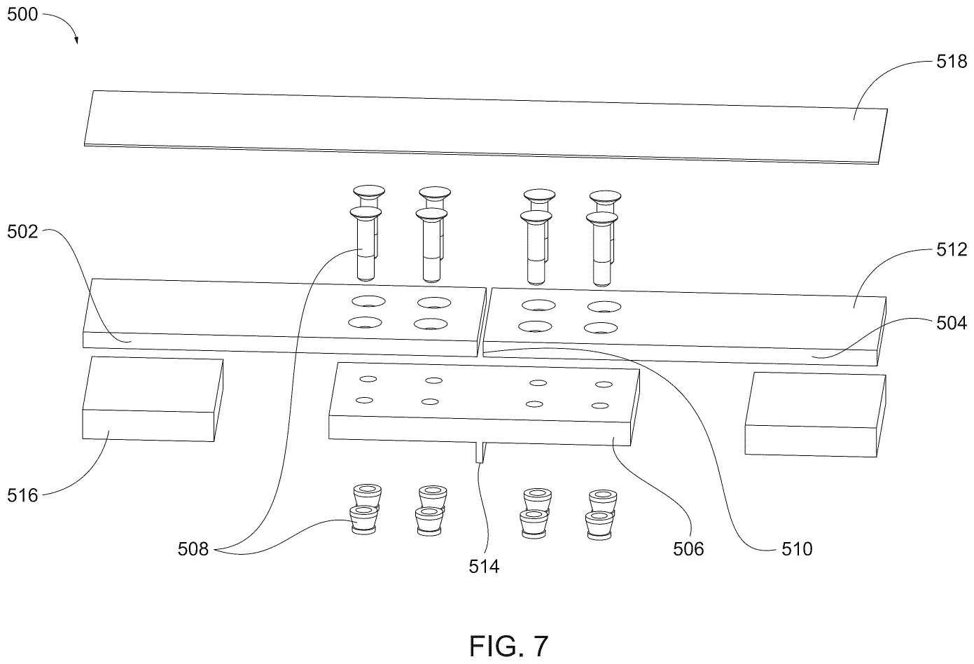

Examples of the method further include constructing 18 a physical coupon based on the coupon FEM, testing the physical coupon, comparing a physical coupon characteristic to the global-element output, and constructing a further coupon FEM based on the comparing. Constructing 18 may also be described as fabricating or assembling. Examples of the physical coupon have similar components, characteristics, and dimensions to those modeled in the coupon FEM. In one example depicted in FIGS. 5-7, the physical coupon 500 comprises physical panels 502, 504, a physical backing 506, a physical connection 508, a physical joint 510, a physical outer surface 512, a physical spar 514, physical tabs 516, and a physical coating 518. In this example, the two panels 502, 504 of the physical coupon 500 have approximately the same dimensions and stiffness as the represented two panels 302, 304 of the coupon FEM. However, exact dimensions and characteristics of the physical coupon vary, due to factors such as manufacturing tolerances, inconsistencies in material, temperature, and the like.

Physical coupons will vary in composition. One example of a physical coupon 500 comprises physical panels 502, 504 of composite or metallic outer mold line skins. Another example of a physical coupon 500 comprises a physical connection 508 of metallic fasteners such as rivets.

Construction of a physical coupon allows for physical testing of modeled structures. For example, a global FEM represents loads and displacements in a particular joint of a wing, and a coupon FEM models an apparatus for simulating the joint of the global FEM. However, in one example, the initial coupon FEM does not adequately represent the joint of the global FEM. Examples of a second coupon FEM are similar to the first coupon FEM, but comprise one or more changes to reduce one or more differences between the first coupon FEM and the global FEM. An example of reducing the difference between the first coupon FEM and the global FEM improves correlation of a parameter between the coupon FEM and the global FEM. Once a coupon FEM is within a threshold of the global FEM, then a physical coupon can be constructed based on the coupon FEM. This process allows for increased accuracy in physical testing of elements based on both the coupon FEM and global FEM.

Examples of the method further include comparing one or more characteristics of the physical coupon to characteristics or elements of the global FEM. In one example, the global FEM represents a frame of a vehicle or an aircraft, and the output of the global FEM is a load and displacement at a joint. In this example, the output of the global FEM is compared to a load and displacement of the joint of a physical coupon which was constructed based on a coupon FEM. Furthermore, a further coupon FEM may be generated based on the results of the comparing of the physical coupon characteristic to the global-element output.

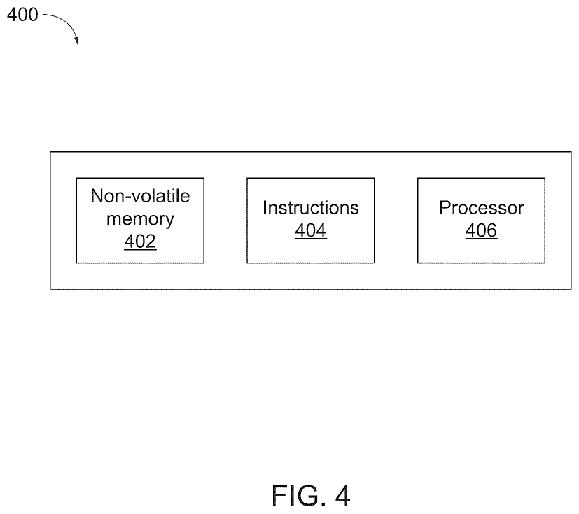

In an example where the physical coupon 500 comprises physical panels 502, 504, physical backing 506, physical connection 508, physical joint 510, physical outer surface 512, physical spar 514, physical tabs 516, and physical coating 518, an output of a global FEM is displacement and strain in elements representing coating 218, and the output of a global FEM is compared to a displacement and strain in a coating of the physical coupon determined by testing the physical coupon. Examples of the application also include apparatuses. FIG. 4 depicts an example of an apparatus 400 comprises non-volatile memory 402, instructions 404 stored on the non-volatile memory 402, and a processor 406 configured to execute the instructions 404 to perform the method 10 depicted in FIG. 1. This example of method 10 comprises generating a coupon FEM comprising coupon elements and determining a difference between a global-element output and a coupon-element output.

Further examples include use of apparatus 400 to generate a coupon finite element model comprising coupon elements, and to determine a difference between a global-element output and a coupon-element output.

A controller or processor 406 may be any suitable device or devices that are configured to perform the functions of the controller discussed herein. For example, the controller may include one or more of an electronic controller, a dedicated controller, a special-purpose controller, a personal computer, a special-purpose computer, a display device, a logic device, a memory device, and/or a memory device having non-transitory computer-readable media suitable for storing computer-executable instructions for implementing aspects of systems and/or methods according to the present disclosure.

Illustrative, non-exclusive examples of inventive subject matter according to the present disclosure are described in the following enumerated paragraphs:

A. A method 10 comprising:
generating 12 a coupon finite element model (FEM) comprising coupon elements; and
   determining 14 a difference between a global-element output of global elements of a global FEM and a coupon-element output of the coupon elements of the coupon FEM, wherein the global-element output and the coupon-element output comprise one or more of a physical characteristic, dimension, and displacement.

A1. The method 10 of paragraph A, wherein the global FEM is a model of one or more of a structure, a portion of a structure, a vehicle, a portion of a vehicle, an aircraft, or a portion of an aircraft.

A2. The method 10 of any of paragraphs A-A1, wherein the global FEM is a model of one or more of an aircraft wing 222, a fuselage, an empennage, and a chassis.

A2.2 The method 10 of any of paragraphs A-A1, wherein the global FEM compromises global elements representing skin panels 202, 204, a connection 208, a gap 210, an outer surface 212, and a coating 218.

A3. The method 10 of any of paragraphs A-A2, wherein the global-element output compromises a gap displacement in global elements representing a gap 210 in a skin 220.

A4. The method 10 of any of paragraphs A-A3, wherein the coupon elements comprise surface elements representing an outer surface 312.

A5. The method 10 of any of paragraphs A-A4, wherein the coupon elements comprise panel elements representing two panels 302, 304 and support elements representing structures attached to the two panels 302, 304.

A5.1. The method 10 of paragraph A5, wherein the support elements represent one or more of a backing 306, a connection 308 between the backing 306 and the two panels 302, 304, a spar 314, and tabs 316.

A5.1.1 The method 10 of paragraph A5.1, wherein the connection 308 comprises one or more of a bolt, a bond, a rivet, a flocking, or an adhesive.

A5.1.2. The method 10 of any of paragraphs A5-A5.1, wherein the coupon-element output comprises a change in dimension of a joint 310 between the two panels 302, 304.

A5.1.3. The method 10 of any of paragraphs A5-A5.1, wherein the coupon-element output comprises a movement of a/the connection 308.

A5.1.4. The method 10 of any of paragraphs A5-A5.1, wherein the coupon-element output comprises yielding in an element of the coupon FEM.

A5.1.5. The method 10 of any of paragraphs A5-A5.1, wherein the coupon-element output comprises a change dimension.

A5.1.6. The method 10 of any of paragraphs A5-A5.1, wherein the coupon-element output comprises a change dimension representing damage.

A5.1.7. The method 10 of any of paragraphs A5-A5.1, wherein the coupon-element output comprises a strain within coating elements representing a coating 318.

A6. The method 10 of any of paragraphs A-A5.1.6, wherein the coupon FEM comprises coating elements representing a coating 318.

A6.1. The method 10 of paragraph A6 when depending from paragraph A5.1.2, wherein the coating elements are positioned over the coupon elements representing the joint 310 between the two panels 302, 304.

A6.1.1. The method 10 of any of paragraphs A6-A6.1, wherein a thickness of the represented coating 318 is at least 0.025 millimeters (mm).

A7. The method 10 of any of paragraphs A-A6.1.1, wherein the coupon FEM simulates physical characteristics, and wherein the physical characteristics comprise one or more of stiffness, thermal expansion, friction, bearing damage, and metal plasticity.

A8. The method 10 of any of paragraphs A-A7, further comprising:
constructing 18 a physical coupon based on the coupon FEM;
testing the physical coupon; and
comparing a physical coupon characteristic to the global-element output; and
constructing a further coupon FEM based on the comparing the physical coupon characteristic to the global-element output.

A9. The method 10 of any of paragraphs A-A8, further comprising determining 16 if the difference exceeds one or more threshold.

A9.1. The method 10 of paragraph A9, wherein the coupon FEM is a first coupon FEM, the coupon elements are first coupon elements 302-318, the difference is a first difference, and the coupon-element output is a first coupon-element output; the method 10 further comprising:
responsive to the first difference exceeding the one or more threshold, generating 12 a second coupon FEM comprising second coupon elements 302-318, wherein at least one of the second coupon elements is different from the first coupon elements; and
determining 14 a second difference between the global-element output of the global elements of the global FEM and a second coupon-element output of the second coupon elements.

A9.1.1. The method 10 of paragraph A9.1, wherein the one or more threshold is a first threshold, the method 10 further comprising:
responsive to the second difference exceeding a second threshold, generating 12 a third coupon FEM comprising third coupon elements, wherein at least one of the third coupon elements is different from the second coupon elements and from the first coupon elements; and
determining 14 a third difference between the global-element output of the global elements of the global FEM and a third coupon-element output of the third coupon elements of the third coupon FEM.

A9.1.1.1. The method 10 of paragraph A9.1.1, wherein the third difference is less than the second difference and the second difference is less than the first difference.

A9.2. The method 10 of paragraph A9.1, wherein the second coupon elements 302-318 represent a backing 306 or a connection 308 that is different from the first coupon elements 302-318.

A9.3. The method 10 of paragraph A9, wherein the second coupon elements comprise connection elements representing an additional connection not present in the first coupon elements.

A9.4. The method 10 of paragraph A9, wherein the second coupon elements represent at least one material that is different from the first coupon elements.

A10. The method 10 of any of paragraphs A-A9.4, wherein the one or more of the physical characteristic, dimension, and displacement comprises one or more of friction, damage, metal plasticity, stiffness, displacement, fastener movement, thermal effects, dimension misalignment, and clearance.

A11. The method 10 of any of paragraphs A-A10, wherein the coupon elements 302-318 comprise part elements representing two structures and joining elements representing components joining the two structures.

A12. The method 10 of any of paragraphs A-A11, constructing 18 a/the physical coupon based on the coupon FEM in response to the difference being less than a/the threshold.

B. An apparatus 400 comprising:
non-volatile memory 402;
instructions 404 stored on the non-volatile memory 402; and
a processor 406 configured to execute the instructions 404 to perform the method 10 of any of paragraphs A-A11.

C. Use of the apparatus 400 of paragraph B to perform the method of any of paragraphs A-A12.

As used herein, the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa. Similarly, subject matter that is recited as being configured to perform a particular function may additionally or alternatively be described as being operative to perform that function.

As used herein, the term “and/or” placed between a first entity and a second entity means one of (1) the first entity, (2) the second entity, and (3) the first entity and the second entity. Multiple entries listed with “and/or” should be construed in the same manner, i.e., “one or more” of the entities so conjoined. Other entities optionally may be present other than the entities specifically identified by the “and/or” clause, whether related or unrelated to those entities specifically identified. Thus, as a non-limiting example, a reference to “A and/or B,” when used in conjunction with open-ended language such as “comprising,” may refer, in one example, to A only (optionally including entities other than B); in another example, to B only (optionally including entities other than A); in yet another example, to both A and B (optionally including other entities). These entities may refer to elements, actions, structures, steps, operations, values, and the like.

The various disclosed elements of apparatuses and steps of methods disclosed herein are not required to all apparatuses and methods according to the present disclosure, and the present disclosure includes all novel and non-obvious combinations and subcombinations of the various elements and steps disclosed herein. Moreover, one or more of the various elements and steps disclosed herein may define independent inventive subject matter that is separate and apart from the whole of a disclosed apparatus or method. Accordingly, such inventive subject matter is not required to be associated with the specific apparatuses and methods that are expressly disclosed herein, and such inventive subject matter may find utility in apparatuses and/or methods that are not expressly disclosed herein.

1. A method comprising:
generating a coupon finite element model (FEM) comprising coupon elements; and
determining a difference between a global-element output of global elements of a global FEM and a coupon-element output of the coupon elements of the coupon FEM, wherein the global-element output and the coupon-element output comprise one or more of a physical characteristic, dimension, and displacement.

2. The method of claim 1, wherein the global FEM is a model of one or more of a structure, a portion of a structure, a vehicle, a portion of a vehicle, an aircraft, or a portion of an aircraft.

3. The method of claim 1, wherein the global-element output compromises a gap displacement in the global elements representing a gap in a skin.

4. The method of claim 1, wherein the coupon elements comprise panel elements representing two panels, and support elements representing structures attached to the two panels.

5. The method of claim 4, wherein the support elements represent one or more of a backing, a connection between the backing and the two panels, a spar, and tabs.

6. The method of claim 1, wherein the coupon-element output comprises a change in a dimension of a joint between two panels.

7. The method of claim 1, wherein the coupon-element output comprises a movement of a connection.

8. The method of claim 1, wherein the coupon-element output comprises a strain within coating elements representing a coating.

9. A method comprising:
generating a coupon finite element model (FEM) comprising coupon elements; and
determining a difference between a global-element output of global elements of a global FEM and a coupon-element output of the coupon elements of the coupon FEM, wherein the global-element output and the coupon-element output comprise one or more of a physical characteristic, dimension, and displacement;
wherein the coupon FEM simulates physical characteristics, and wherein the physical characteristics comprise one or more of friction, damage, metal plasticity, stiffness, displacement, fastener movement, thermal effects, dimension misalignment, and clearance.

10. The method of claim 9, further comprising:
constructing a physical coupon based on the coupon FEM;
testing the physical coupon;
comparing a physical coupon characteristic to the global-element output; and
constructing a further coupon FEM based on the comparing the physical coupon characteristic to the global-element output.

11. The method of claim 9, further comprising constructing a physical coupon based on the coupon FEM in response to the difference being less than a threshold.

12. The method of claim 9, further comprising determining if the difference exceeds one or more threshold.

13. The method of claim 12, wherein the coupon FEM is a first coupon FEM, the coupon elements are first coupon elements, the difference is a first difference, and the coupon-element output is a first coupon-element output; the method further comprising:
responsive to the first difference exceeding the one or more threshold, generating a second coupon FEM comprising second coupon elements, wherein at least one of the second coupon elements is different from the first coupon elements; and
determining a second difference between the global-element output of the global elements of the global FEM and a second coupon-element output of the second coupon elements.

14. The method of claim 13, wherein the one or more threshold is a first threshold, the method further comprising:
responsive to the second difference exceeding a second threshold, generating a third coupon FEM comprising third coupon elements, wherein at least one of the third coupon elements is different from the second coupon elements and from the first coupon elements; and
determining a third difference between the global-element output of the global elements of the global FEM and a third coupon-element output of the third coupon elements of the third coupon FEM.

15. The method of claim 14, wherein the third difference is less than the second difference, and the second difference is less than the first difference.

16. The method of claim 13, wherein the second coupon elements represent a backing or a connection that is different from the first coupon elements.

17. The method of claim 13, wherein the second coupon elements comprise connection elements representing an additional connection that is not present in the first coupon elements.

18. The method of claim 9, wherein the one or more of the physical characteristic, dimension, and displacement comprises stiffness, friction, fastener movement, damage, metal plasticity, thermal effects, dimension misalignment, and clearance.

19. The method of claim 9, wherein the coupon elements comprise part elements representing two structures and joining elements representing components joining the two structures.

20. An apparatus comprising:
non-volatile memory;
instructions stored on the non-volatile memory; and
a processor configured to execute the instructions to perform:
generating a coupon finite element model (FEM) comprising coupon elements; and
determining a difference between a global-element output of global elements of a global FEM and a coupon-element output of the coupon elements of the coupon FEM; wherein the global-element output and the coupon-element output comprise one or more of a physical characteristic, dimension, and displacement.
